(19) United States
(12) Patent Application Publication
(10) Pub. No.: US 2016/0079371 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventors: Chisato FURUKAWA, Komatsu Ishikawa (JP); Masaaki OGAWA, Sagamihara Kanagawa (JP); Takako MOTAI, Yokohama Kanagawa (JP)

(21) Appl. No.: 14/635,279

(22) Filed: Mar. 2, 2015

(30) Foreign Application Priority Data
Sep. 12, 2014 (JP) 2014-186895

(51) Int. Cl. H01L 29/20; H01L 21/02; H01L 29/778; H01L 21/28; H01L 29/205; H01L 29/51

(52) U.S. Cl. CPC H01L 29/2003; H01L 29/205; H01L 29/513; H01L 29/518; H01L 29/517; H01L 29/7787; H01L 21/28264; H01L 21/02274; H01L 21/02282; H01L 21/0217

(57) ABSTRACT

According to one embodiment, there is provided a semiconductor device including a first semiconductor layer, a second semiconductor layer, a first insulating film, a first electrode, and a second insulting film. The first semiconductor layer includes a compound semiconductor. The second semiconductor layer is provided on the first semiconductor layer and includes a compound semiconductor. The first insulating film is provided on the second semiconductor layer. The first electrode is provided on the first insulating film. The second insulting film covers at least a portion of the first electrode and has a higher hydrogen concentration than the hydrogen concentration of the first insulating film.

### CROSS-REFERENCE TO RELATED APPLICATION

This application is based upon and claims the benefit of priority from Japanese Patent Application No. 2014-186895, filed Sep. 12, 2014, the entire contents of which are incorporated herein by reference.

### FIELD

Embodiments described herein relate generally to a semiconductor device.

### BACKGROUND

A compound semiconductor such as a gallium nitride-based semiconductor has a wider band gap as compared with the band gap of silicon. Such a compound semiconductor is used for a semiconductor device such as a transistor. When a voltage is applied to a transistor, a change in characteristics with time, such as the ON resistance, may occur. For this reason, the lifetime during which desired characteristics may be obtained is limited, and reliability of the semiconductor device may be decreased. It is desired to increase reliability in the semiconductor device.

### DESCRIPTION OF THE DRAWINGS

FIG. 1 has a part (a) that is a schematic sectional view of a semiconductor device, and a part (b) that is a graph showing the relative hydrogen concentration of different portions of the semiconductor device according to a first embodiment.

FIG. 2A to FIG. 2D are schematic sectional views illustrating the results of processing steps in a method of fabricating a semiconductor device according to the first embodiment.

FIG. 3 has a part (a) that is a schematic sectional view of a semiconductor device, and a part (b) that is a graph showing the relative hydrogen concentration of different portions of the semiconductor device according to a second embodiment.

FIG. 4A to FIG. 4D are schematic sectional views illustrating the results of processing steps in a method of fabricating a semiconductor device according to the second embodiment.

### DETAILED DESCRIPTION

Exemplary embodiments provide a semiconductor device with increased reliability.

In general, according to one embodiment, a semiconductor device comprises a first semiconductor layer, a second semiconductor layer, a first insulating film, a first electrode, and a second insulting film. The first semiconductor layer comprises a compound semiconductor. The second semiconductor layer is provided on the first semiconductor layer and comprises a compound semiconductor. The first insulating film is provided on the second semiconductor layer. The second insulting film covers at least a portion of the first electrode and has a higher hydrogen concentration than the hydrogen concentration of the first insulating film.

Hereinafter, each exemplary embodiment will be described with reference to the drawings.

In addition, the drawings are schematic and conceptual, and a relationship between thickness and width of each portion, a size ratio between the portions, and the like are not necessarily limited to the same as the real. In addition, where different drawing figures show the same elements, the respective dimensions and ratios thereof may be depicted differently.

In addition, in the present specification and each drawing figure, the same reference numerals are attached to the same elements as those previously illustrated, and detailed description thereof will be omitted as appropriate.

In the present specification, for convenience of description, the terms “on” and “under” will be used. The term “provided on” includes not only a case where “one provided on something” is in direct contact with “the something provided under the one”, but also a case where another element is interposed therebetween.

### First Embodiment

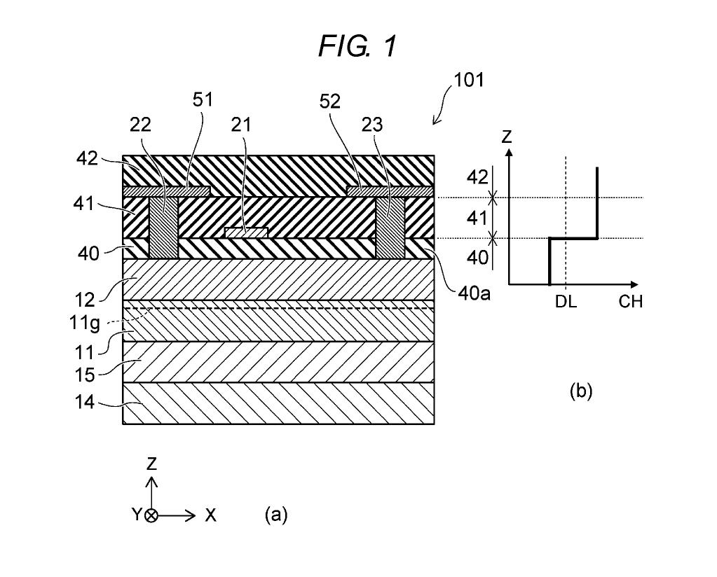

In FIG. 1, parts (a) and (b) are schematic views illustrating a semiconductor device according to a first embodiment.

Part (a) of FIG. 1 is a schematic cross-sectional view of a semiconductor device 101. The semiconductor device 101 is a high electron mobility transistor (HEMT) that uses, for example, a nitride semiconductor as a material.

As illustrated in part (a) of FIG. 1, the semiconductor device 101 includes a first semiconductor layer 11, a second semiconductor layer 12, a first insulating film (hereinafter, referred to as “gate insulating film 40”), a first electrode (hereinafter, referred to as “gate electrode 21”), a second electrode (hereinafter, referred to as “source electrode 22”), and a third electrode (hereinafter, referred to as “drain electrode 23”). Furthermore, the semiconductor device 101 includes a substrate 14, a buffer layer 15, a first wiring layer 51, a second wiring layer 52, a second insulating film (hereinafter, referred to as “interlayer insulating film 41”), and a third insulating film (hereinafter, referred to as “insulating film 42”).

In part (a) of FIG. 1, a direction extending toward the second semiconductor layer 12 from the first semiconductor layer 11 is referred to as a Z axis direction. One direction that is perpendicular to the Z axis direction is referred to as an X axis direction. A direction that is perpendicular to the Z axis direction and the X axis direction is referred to as a Y axis direction.

As a material of the substrate 14, silicon, germanium, silicon carbide (SiC), diamond, sapphire, boron nitride (BN), gallium nitride (GaN), or the like is used.

The buffer layer 15 is provided on the substrate 14. The buffer layer 15 includes a plurality of aluminum nitride layers (AlN layer), a layer (AlGaN layer) including a plurality of AlₓGa₁₋ₓN layers and a plurality of GaN layers. Each layer is repeatedly stacked in the sequence of an AlN layer-an AlGaN layer-a GaN layer, in a stacking direction extending from the substrate 14 and the buffer layer 15. In this case, the buffer layer 15 has a structure (superlattice structure) in which a layer structure of AlN—AlGaN—GaN is periodically repeated. However, not being limited to this, the buffer layer 15 may include a plurality of AlGaN layers in which a composition ratio of Al is changed step by step in the stacking direction. The buffer layer 15 may be one layer (so-called an inclined layer) in which the composition ratio of Al is continuously changed toward GaN from AlN. In addition, the buffer layer 15 is provided as necessary, and may be omitted.

The first semiconductor layer 11 is provided on the buffer layer 15. The first semiconductor layer 11 is a channel layer, and includes Alₓ₁Ga₁₋ₓ₁N (0≦x1<1).

The second semiconductor layer 12 is provided on the first semiconductor layer 11. The second semiconductor layer 12 is a barrier layer, and includes Alₓ₂Ga₁₋ₓ₂N (x1<x2<1). The second semiconductor layer 12 forms a heterojunction with the first semiconductor layer 11. A thickness (length along the Z axis direction) of the second semiconductor layer 12 is equal to or greater than 20 nanometers (nm) and equal to or less than 40 nm.

At a junction interface between the first semiconductor layer 11 and the second semiconductor layer 12, the first semiconductor layer 11 is stressed. As a result, a region of high electron mobility, including free electrons, is formed in the vicinity of the junction interface of the first semiconductor layer 11, by a piezoresistive effect.

The source electrode 22 and the drain electrode 23 are respectively provided on the second semiconductor layer 12, and are electrically coupled to the second semiconductor layer 12. The source electrode 22 is separately positioned, i.e., spaced, in the X axis direction from the drain electrode 23. Widths of the source electrode 22 and the drain electrode 23 are respectively equal to or greater than 3 micrometers (μm) and equal to or less than 8 μm.

As a material of the source electrode 22 and the drain electrode 23, aluminum (Al), titanium (Ti), nickel (Ni), gold (Au), tungsten (W), molybdenum (Mo), tantalum (Ta), or the like may be used.

The gate electrode 21 is provided between the source electrode 22 and the drain electrode 23. A width (for example, length along the X axis direction) of the gate electrode 21 is equal to or greater than 1.0 micrometers (μm) and equal to or less than 3.0 μm. A distance between the gate electrode 21 and the source electrode 22 is equal to or greater than 1 μm and equal to or less than 3 μm. A distance between the gate electrode 21 and the drain electrode 23 is equal to or greater than 5 μm and equal to or less than 20 μm. As a material of the gate electrode 21, aluminum (Al), titanium (Ti), nickel (Ni), gold (Au), or the like may be used.

The gate insulating film 40 is provided on the second semiconductor layer 12, and the gate electrode 21 is provided on the gate insulating film 40. A thickness of the gate insulating film 40 is equal to or greater than 5 nm and equal to or less than 50 nm. As a material of the gate insulating film 40, silicon nitride (SiN), silicon oxide (SiO₂), aluminum oxide (Al₂O₂), titanium oxide (TiO₂), tantalum oxide (Ta₂O₅), hafnium oxide (HfO₂), zirconium oxide (ZrO₂), or the like is used. The gate insulating film 40 is formed as a single layer (first layer 40a).

The interlayer insulating film 41 covers at least a portion of the gate electrode 21 and a portion of the gate insulating film 40. The interlayer insulating film 41 is in contact with a portion of the gate electrode 21 and a portion of the gate insulating film 40. A portion of the interlayer insulating film 41 is positioned between the gate electrode 21 and the source electrode 22, and between the gate electrode 21 and the drain electrode 23.

As a material of the interlayer insulating film 41, SiN is used. The hydrogen concentration of the interlayer insulating film 41 is 1×10¹⁸ atoms/cm³ to 1×10²³ atoms/cm³.

The wiring layer 51 is provided on the source electrode 22, and is electrically coupled to the source electrode 22. The wiring layer 52 is provided on the drain electrode 23, and is electrically coupled to the drain electrode 23.

The insulating film 42 is provided on the wiring layer 51, the wiring layer 52, and the interlayer insulating film 41. As a material of the insulating film 42, SiN or SiO₂ is used.

Part (b) of FIG. 1 is a graph illustrating a distribution of hydrogen concentration of the semiconductor device 101, illustrating the hydrogen concentration of the gate insulating film 40, the interlayer insulating film 41, and the insulating film 42 in the thickness direction thereof. A vertical axis of part (b) in FIG. 1 denotes a position in the layers as measured along the Z axis direction. A horizontal axis of part (b) of FIG. 1 denotes relative hydrogen concentration CH of the layers.

As illustrated in part (b) of FIG. 1, the hydrogen concentration of the gate insulating film 40 is lower than the hydrogen concentration of the interlayer insulating film 41.

The gate insulating film 40 does not contain hydrogen. Here, the term “does not contain hydrogen” means that concentration of hydrogen is equal to or lower than, (i.e., below) the detection limit DL of hydrogen using secondary ion mass spectrometry (SIMS) with respect to a film (layer) with a thickness of a general gate insulating film. The thickness (length along the Z axis direction) of the general gate insulating film is equal to or greater than 5 nanometers (nm) and equal to or less than 50 nm. A diameter of an area analyzed by the SIMS is equal to or greater than 10 μm and equal to or less than 100 μm. Hydrogen concentration of the gate insulating film 40 is equal to or less than, for example, 1×10¹⁵ atoms/cm³, the lower detection limit of hydrogen by SIMS

Furthermore, the concentration of N—H bonds in the gate insulating film 40 is less than the concentration of N—H bonds in the interlayer insulating film 41. In addition, the concentration of N—H bonds is measured using Fourier transform Infrared Spectroscopy (FTIR).

Next, a method of fabricating the semiconductor device 101 will be described.

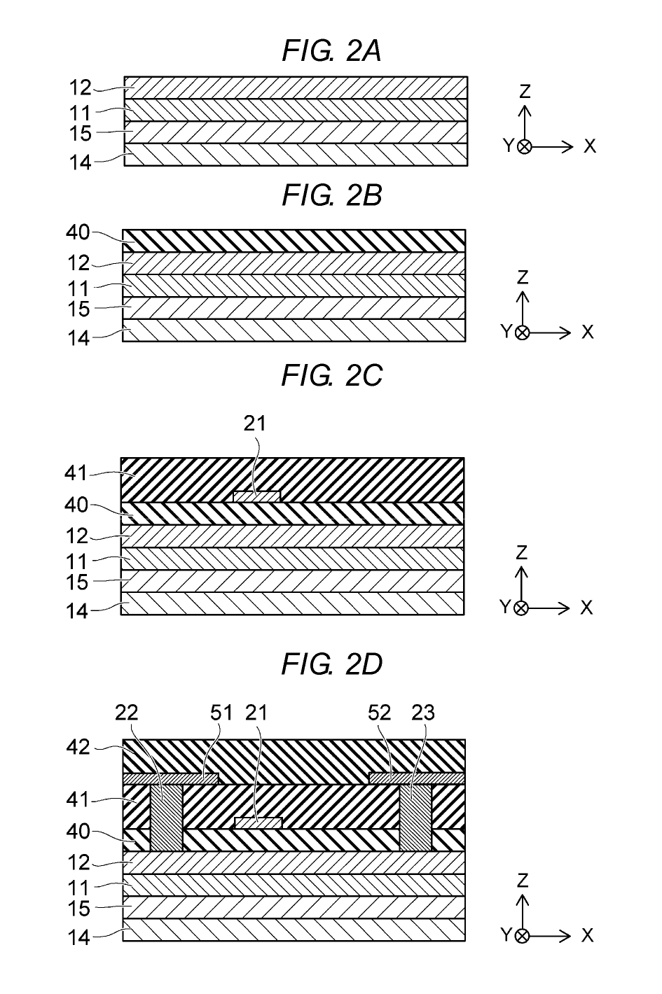

FIG. 2A to FIG. 2D are schematic views illustrating the physical result of process steps in a method of fabricating the semiconductor device according to the first embodiment.

As illustrated in FIG. 2A, the buffer layer 15 is first formed on the substrate 14 (Si substrate) having a (111) plane. Subsequently, the first semiconductor layer 11 and the second semiconductor layer 12 are sequentially formed thereover. Such layers are formed in an epitaxially using a metal organic chemical vapor deposition (MOCVD) method.

Here, hydrogen is taken into the first semiconductor layer 11 and the second semiconductor layer 12 that are gallium nitride-based, immediately after crystalline growth thereof.

Thereafter, as illustrated in FIG. 2B, the gate insulating film 40 is formed on the second semiconductor layer 12. The gate insulating film 40 is formed as follows. The second semiconductor layer 12 is first coated with liquid phase chemical material using a spin coating method. As the liquid phase chemical material, silicon-containing compound (for example, silicon nitride (SiNx), silicon oxynitride (SiON), silicon hydroxide, polysilazane, or the like) may be used. Subsequently, in a nitrogen atmosphere or a vacuum, thermal processing is performed. As a result, the gate insulating film 40 is formed. In addition, hydrogen contained in the first semiconductor layer 11 and the second semiconductor layer 12 is removed from the semiconductor layers by such thermal processing.

Thereafter, as illustrated in FIG. 2C, a TiN film serving as the gate electrode 21 is formed on the gate insulating film 40, and the TiN film is processed using a photolithographically patterned mask and etching of the TiN film layer to form the gate electrode 21. The TiN film may be formed by a physical vapor deposition (PVD) method, for example. For etching of the film into the individual gate electrode 21, a reactive ion etching (RIE) method can be used.

Subsequently, a SiN film serving as the interlayer insulating film 41 is formed so as to cover the gate insulating film 40 and the gate electrode 21. In order to form the SiN film, a plasma CVD method may be used. In order to form the SiN film using the plasma CVD method, SiH₄ gas, NH₃ gas, and N₂ gas are used.

When the SiN film is formed, a wafer is exposed to plasma containing hydrogen. For this reason, the SiN film formed using the plasma CVD method contains hydrogen in a large amount as compared with the gate insulating film 40. In addition, it is also considered that the hydrogen is mixed into the gate insulating film 40 as a result of migration thereof from the interlayer insulating film 41. However, the width of the gate electrode 21 formed on the gate insulating film 40 is wider than the thickness of the gate insulating film 40. For this reason, the quantity of hydrogen which reaches to, and mixes with, the gate insulating film 40 in the area below the gate electrode 21, i.e., between the gate electrode 21 and the second semiconductor film layer 12, is minimal.

Thereafter, as illustrated in FIG. 2D, the source electrode 22 and the drain electrode 23 are formed. In order to form the source electrode 22 and the drain electrode 23, an opening is first formed in the SiN film 41 at the position where an electrode is to be provided, and a metal film (for example, a Titanium (Ti) barrier film and Aluminum (Al) film over the Ti and filling the opening) is formed by a sputtering method. Then, portions of the metal film overlying the SiN film 41 are processed by photolithographic patterning of a mask and etching the Ti and Al film top individually form the source electrode 22 and the drain electrode 23.

Thereafter, the wiring layers 51 and 52, and the like are formed using sputtering, lithographic patterning of a mask layer thereover, and etching the wiring layer film to form the wiring layers 51, 52. A SiO₂ film serving as the insulating film 42 is formed on the wires 51 and 52 using the plasma CVD method, and the semiconductor device 101 is completed.

The composition ratio of Al of the second semiconductor layer 12 is higher than the composition ratio of Al of the first semiconductor layer 11. For this reason, a lattice constant of the first semiconductor layer 11 is different from a lattice constant of the second semiconductor layer 12. Due to this, distortion occurs at the interface of the two layers, and a two-dimensional high electron mobility region 11g is formed in the semiconductor material in the vicinity of the interface between the first semiconductor layer 11 and the second semiconductor layer 12.

In the semiconductor device 101, a voltage applied to the gate electrode 21 is controlled, and thus concentration of the two-dimensional high electron mobility region 11g under the gate electrode 21 is increased and decreased. As a result, a current flowing between the source electrode 22 and the drain electrode 23 is controlled. The semiconductor device 101 is a normally-ON element. In the embodiment, the semiconductor device may be normally-OFF.

According to the present inventors, it is found that in a semiconductor device to which a high voltage is applied, when a large hydrogen quantity (particularly, in N—H bonds) is contained in a gate insulation film, reliability of the semiconductor device degrades. Particularly, when a large quantity of hydrogen is contained in the gate insulating film, the hydrogen is easily taken into an interface of the semiconductor layer (between the first semiconductor layer 11 and the second semiconductor layer 12), or into the semiconductor layers 11 and 12. For example, when hydrogen is taken into the semiconductor layer, it is considered that a defect of the semiconductor layer is induced, and an energy level of the interface of the first semiconductor layer 11 is changed. As a result, density or mobility of carrier (two-dimensional high electron mobility region) of the first semiconductor layer 11 is changed. For example, the mobility of these electrons is changed, and the threshold voltage for opening the gate of a transistor is changed. In addition, the density of electrons in the two-dimensional electron region is lowered, and an ON resistance is sometimes increased. While the semiconductor device is used, when much hydrogen becomes incorporated into the semiconductor layer, a change in the ON resistance or the threshold with time occurs, and thereby desired characteristics of the device are not obtained. The period (lifetime) for obtaining the desired characteristics is short in a semiconductor device containing a large quantity of hydrogen in the gate insulating film. In addition, the lifetime of a semiconductor device is evaluated by, for example, a high temperature baking test (HTB).

In contrast to this, in the gate insulating film 40 of the semiconductor device 101 according to the embodiment, the hydrogen concentration of the gate insulating film 40 is lower than the hydrogen concentration of the interlayer insulating film 41. For example, the gate insulating film 40 does not contain measurable hydrogen. For this reason, hydrogen is taken into the first semiconductor layer 11 and the second semiconductor layer 12 in negligible amounts from the gate insulating film 40. For this reason, in the first semiconductor layer 11 and the second semiconductor layer 12, defects caused by the hydrogen hardly occurs. In the interface in which two-dimensional high electron mobility region is generated, a change of the energy level caused by the defect seldom occurs. As a result, in the semiconductor device that uses the two-dimensional high electron mobility region as a channel, a change of density or mobility of carrier barely occurs. For this reason, it is possible to decrease variation of characteristics such as an ON resistance, an ON-current, and a threshold voltage, and to increase device reliability.

### Second Embodiment

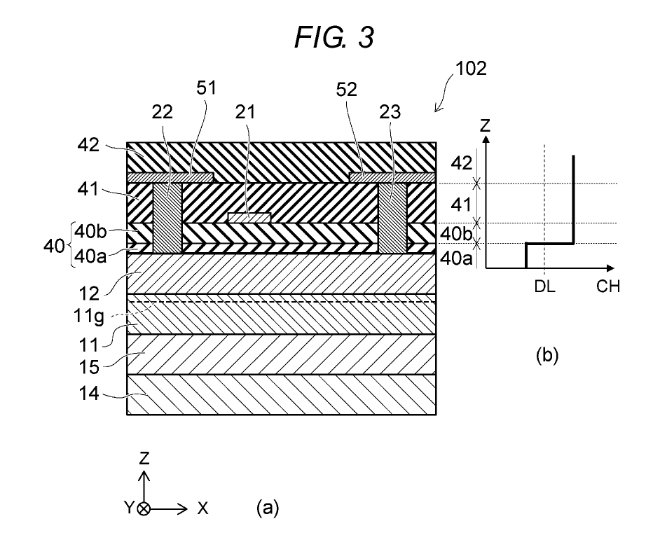

Part (a) of FIG. 3 is a schematic sectional view of a semiconductor device 102.

The semiconductor device 102 is different from the semiconductor device 101 according to the first embodiment, in the gate insulating film 40 thereof. With regard to the other configurations, the same reference numerals are attached to the same configuration elements as that described with regard to the semiconductor device 101, and description thereof will be omitted.

A thickness of the gate insulating film 40 of the semiconductor device 102 may be equal to the thickness of the gate insulating film 40 in the semiconductor device 101.

In the present embodiment, the gate insulating film 40 has a multi-layered structure. The gate insulating film 40 includes a first layer 40a and a second layer 40b.

As a material of the first layer 40a, SiN is used. A thickness of the first layer 40a is equal to or greater than one atomic layer, for example, equal to or greater than 1 nm and equal to or less than 10 nm.

The second layer 40b is provided on the first layer 40a. As a material of the second layer 40b, SiN is used. The SiN film that is used for the second layer 40b is denser than the SiN film that is used for the first layer 40a. That is, density of the second layer 40b is higher than density of the first layer 40a. A thickness of the second layer 40b is a value that is obtained by subtracting a thickness of the first layer 40a from a design value of a thickness of the gate insulating film 40.

Part (b) of FIG. 3 is a graph illustrating the distribution of hydrogen concentration of the semiconductor device 102. Part (b) of FIG. 3 illustrates hydrogen concentrations of the first layer 40a, the second layer 40b, the interlayer insulating film 41, and the insulating film 42. A vertical axis of part (b) in FIG. 3 denotes a position along the Z axis direction of the film layers. A horizontal axis of part (b) of FIG. 3 denotes hydrogen concentration CH.

As illustrated in part (b) of FIG. 3, the hydrogen concentration of the first layer 40a is equal to or less than a detection limit of SIMS. That is, a portion of the gate insulating film 40, which is in contact with the second semiconductor layer 12, does not contain measurable hydrogen.

The hydrogen concentration of the second layer 40b is higher than the hydrogen concentration of the first layer 40a. That is, the hydrogen concentration in the gate insulating film 40 increases in the Z axis direction (direction toward the second semiconductor layer 12 from the first semiconductor layer 11).

In addition, the concentration of N—H bonds in the second layer 40b is higher than concentration of N—H bonds in the first layer 40a.

In addition, the first layer 40a may not be clearly separated from the second layer 40b.

The hydrogen concentration or the concentration of N—H bonds in the first layer 40a may not be uniform along the Z axis direction, and may be continuously changed along the Z axis direction. The hydrogen concentration or the concentration of N—H bonds in the second layer 40b may not be uniform along the Z axis direction, and may be continuously changed along the Z axis direction.

Next, a method of fabricating the semiconductor device 102 will be described.

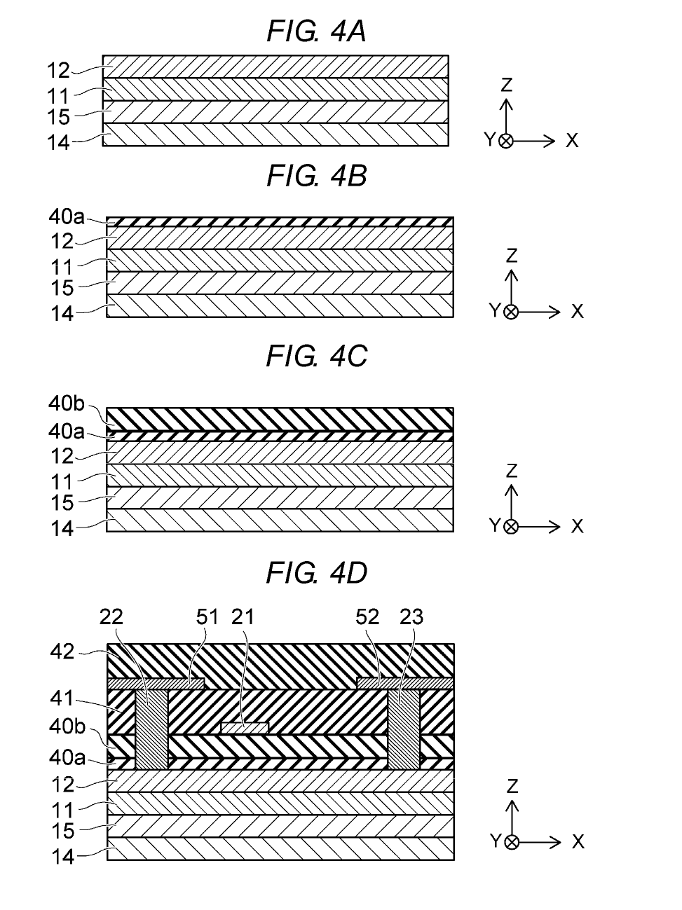

FIG. 4A to FIG. 4D are schematic views illustrating the result of process steps in a method of fabricating the semiconductor device according to the second embodiment.

As illustrated in FIG. 4A, the buffer layer 15, the first semiconductor layer 11, and the second semiconductor layer 12 are sequentially formed on the substrate 14. Such layers are formed in the same manner as those of the first embodiment.

Thereafter, as illustrated in FIG. 4B, the second semiconductor layer 12 is coated with a silicon-containing compound using the spin coating method, and the first layer 40a is formed by heating the substrate 14 in nitrogen atmosphere or a vacuum to cause the silicon layer to be nitrided. In the present embodiment, a thickness of the silicon-containing compound that is used for coating is maintained to a minimum. As a result, a thickness of the first layer 40a becomes extremely thin.

Thereafter, as illustrated in FIG. 4C, the second layer 40b is formed on the first layer 40a. In order to form the second layer 40b, the plasma CVD method may be used.

Thereafter, as illustrated in FIG. 4D, the gate electrode 21, the source electrode 22, the drain electrode 23, the interlayer insulating film 41, the insulating film 42, and the wiring layers 51 and 52 are formed. These are formed in the same manner as those of the first embodiment.

In the present embodiment, the hydrogen concentration of the first layer 40a in contact with the second semiconductor layer 12 is lower than hydrogen concentration of the second layer 40b. The first layer 40a substantially does not contain the hydrogen. For this reason, the hydrogen is barely taken into the first semiconductor layer 11 and the second semiconductor layer 12 from the first layer 40a. For this reason, in the first semiconductor layer 11 and the second semiconductor layer 12, a defect caused by hydrogen barely occurs. In the interface in which the two-dimensional high electron mobility region is generated, a change of an energy level caused by the defect hardly occurs. As a result, in the semiconductor device that uses the two-dimensional high electron mobility region as a channel, a change of density or mobility of carrier hardly occurs. For this reason, it is possible to decrease variations of characteristic such as an ON resistance, an ON-current, and a threshold, and to increase reliability.

Furthermore, in the present embodiment, the SiN film that is used for the second layer 40b is denser than the SiN film that is used for the first layer 40a. For this reason, a current hardly flows through the SiN film that is used for the second layer 40b, as compared to the SiN film that is used for the first layer 40a. The second layer 40b through which the current hardly flows is formed on the first layer 40a, and thereby it is possible to suppress a leakage current (gate leakage) that flows through the entire gate insulating film 40. By suppressing the leakage current, it is possible to suppress power consumption of the semiconductor device 102. In addition, when the leakage current flowing through the gate insulating film 40 becomes large, a defect occurs in the gate insulating film, much larger leakage current flows through the defect, and eventually there is a case where insulation breakdown occurs. In contrast to this, in the present embodiment, the leakage current is suppressed, and thereby it is possible to suppress the occurrence of a defect in the gate insulating film 40, and to suppress the occurrence of insulation breakdown.

In addition, in the present embodiment, a thickness of the first layer 40a is equal to or greater than 1 nm and equal to or less than 10 nm (for example, one atom layer), thereby being thin. Even in this case, the second semiconductor layer 12 is in contact with the first layer 40a that does not contain hydrogen. For this reason, the hydrogen is hardly taken into the second semiconductor layer 12. Then, since the first layer 40a is thin, it is possible to make the thickness of the second layer 40b relatively thick. As a result, in the entire gate insulating film 40, it is possible to expand portions where the current hardly flows, and to further suppress the leakage current.

In addition, in the present specification, the compound semiconductor is a general term fora semiconductor containing two or more elements contained in III-V group (GaAs, GaN, InP or the like), II-VI group (CdTe, ZnSe, CdS or the like), and IV-IV group (SiC, SiGe or the like).

In addition, in the present specification, “nitride semiconductor” contains a III-V group compound semiconductor of BₓIn_{y}Al_{z}Ga_{1-x-y-z}N (0≦x≦1, 0≦y≦1, 0≦z≦1, 0≦x+y+z≦1), and further contains mixed crystal as a V group element containing phosphorus (P), arsenic (As) or the like, in addition to nitride (N). In addition, “nitride semiconductor” includes one further containing various elements that are added to control various physical properties such as conductivity, and one further containing various elements that are unintentionally contained. In addition, “nitride semiconductor” is an example of a compound semiconductor.

In addition, in the present specification, “perpendicular” includes not only strict perpendicular, but also perpendicular including variation in the fabricating step, for example, in a fabrication process and may be actually perpendicular.

As described above, the embodiments are described with reference to specific examples. However, the embodiments are not limited to the specific examples. For example, the specific configuration of each element, such as the first semiconductor layer, the second semiconductor layer, the first insulation film, or the first to third electrodes, is included in the scope of the exemplary embodiments, as long as those skilled in the art implement the exemplary embodiment in the same manner by appropriately selecting configuration from the known range so that the same effect may be obtained.

In addition, as long as not departing from the spirit of the exemplary embodiments, two or more elements of any of the specific examples may be combined within a technically possible range, and this is also included in the scope of the exemplary embodiment.

In addition, as long as not departing from the spirit of the exemplary embodiments, all semiconductor devices that may be obtained by those skilled in the art with an appropriate design modification, based on the semiconductor devices described above as the embodiments according to the exemplary embodiments, are also included in the scope of the exemplary embodiments.

In addition, within a range of spirit of the exemplary embodiments, those skilled in the art may conceive various change examples and modification examples, and such change examples and modification examples are understood as those included in the scope of the exemplary embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer comprising a compound semiconductor;
a second semiconductor layer provided on the first semiconductor layer and comprising a compound semiconductor;
a first insulating film provided on the second semiconductor layer;
a first electrode provided on the first insulating film; and
a second insulting film covering at least a portion of the first electrode and has a higher hydrogen concentration than the hydrogen concentration of the first insulating film.

2. The device according to claim 1,
wherein the first insulating film does not contain measurable hydrogen.

3. The device according to claim 1,
wherein concentration of N—H bonds in the first insulating film is lower than concentration of N—H bonds in the second insulating film.

4. The device according to claim 1,
wherein the first insulating film further comprises a first sub-layer and a second sub-layer provided on the first layer, and
wherein the hydrogen concentration of the first sub-layer is lower than the hydrogen concentration of the second sub-layer.

5. The device according to claim 4,
wherein concentration of N—H bonds of the first sub-layer is lower than concentration of N—H bond of the second sub-layer.

6. The device according to claim 4,
wherein a thickness of the first sub-layer is equal to or greater than one atom layer.

7. The device according to claim 1,
wherein the first insulating film contains at least silicon and nitride.

8. The device according to claim 1,
wherein the hydrogen concentration of the first insulating film increases in the direction toward the second semiconductor layer from the first semiconductor layer.

9. The device according to claim 1,
wherein the first semiconductor layer contains Alₓ₁Ga₁₋ₓ₁N (0≦x1<1), and
wherein the second semiconductor layer contains Alₓ₂Ga₁₋ₓ₂N (x1<x2<1).

10. A semiconductor device, comprising:
a first semiconductor layer;
a second semiconductor layer disposed on the first semiconductor layer;
a strained region located at the contact location of the first semiconductor layer and second semiconductor layer;
a first conductive later disposed on the second semiconductor layer;
a first insulating layer disposed over the second semiconductor layer and the first conductive layer; and
a second insulating layer disposed over the first insulating layer, wherein
the hydrogen concentration of at least a portion of the first insulating layer is below the detection limit of hydrogen using the SIMS method.

11. The semiconductor device of claim 10, wherein the material composition of the first insulating layer and the composition of the second insulating layer are different.

12. The semiconductor device of claim 11, wherein the first insulating layer and the second insulating layer comprise silicon.

13. The semiconductor device of claim 11, wherein the first insulating layer comprises at least one of silicon nitride (SiN), silicon oxide (SiO₂), aluminum oxide (Al₂O₃), titanium oxide (TiO₂), tantalum oxide (Ta₂O₅), hafnium oxide (HfO₂), zirconium oxide (ZrO₂) and the second insulating layer comprise silicon nitride.

14. The semiconductor device of claim 11, wherein
the first insulating layer includes a first sub-layer disposed adjacent to the second semiconductor layer and a second sub-layer disposed over the first sub-layer; and
the hydrogen concentration of the first sub-layer of the first insulating layer is below the detection limit of hydrogen using the SIMS method.

15. The semiconductor device of claim 14, wherein the second sub-layer has a hydrogen concentration detectable by the SIMS method.

16. The semiconductor device of claim 15, wherein the concentration of N—H bonds in the first insulating layer is lower than the concentration of N—H bonds in the second insulating layer.

17. The semiconductor device of claim 15, wherein the density of the first sub-layer is less than the density of the second sub-layer.

18. The semiconductor device of claim 10, wherein the hydrogen concentration of the portion of the first insulating layer contacting the second semiconductor layer is below the limit of hydrogen detection by the SIMS method.

19. A method of forming a semiconductor device having a strained interface region at a connecting portion of a first semiconductor layer and a second semiconductor layer, comprising:
forming a first insulating layer over the second semiconductor layer, wherein the portion of the first insulating layer contacting the second semiconductor layer has a hydrogen concentration below the detection limit of hydrogen by a SIMS method; and
forming a second insulating layer over the first insulating layer.

20. The method of claim 19, further comprising forming the first insulating layer using a spin coating method, and forming the second insulating layer using a plasma process in the presence of hydrogen.
